(19) United States
(12) Patent Application Publication
(10) Pub. No.: US 2014/0261619 A1
(43) Pub. Date: Sep. 18, 2014

(54) INTERCONNECTOR AND SOLAR CELL MODULE HAVING THE SAME

(71) Applicant: LG ELECTRONICS INC., Seoul (KR)

(72) Inventors: Minpyo KIM, Seoul (KR); Taeyoon KIM, Seoul (KR); Bojoong KIM, Seoul (KR); Daehee JANG, Seoul (KR)

(73) Assignee: LG ELECTRONICS INC., Seoul (KR)

(21) Appl. No.: 14/218,593

(22) Filed: Mar. 18, 2014

(30) Foreign Application Priority Data
Mar. 18, 2013 (KR) 10-2013-0028416

(51) Int. Cl. H01L 31/05

(52) U.S. Cl. CPC H01L 31/05
USPC 136/244; 174/126.1

(57) ABSTRACT

An interconnector is discussed, which includes a conductive metal of a band shape including a first surface and a second surface opposite the first surface; and a solder coated on the first surface, wherein the first surface of the conductive metal includes at least a flattened peak extending in a length direction of the conductive metal, the flattened peak including an inclined portion and a flat portion extending in a width direction of the conductive metal, and wherein a length of the inclined portion is less than a length of the flat portion in the width direction of the conductive metal.

This application claims priority to and the benefit of Korean Patent Application No. 10-2013-0028416 filed in the Korean Intellectual Property Office on Mar. 18, 2013, the entire contents of which are incorporated herein by reference.

### BACKGROUND OF THE INVENTION

1. Field of the Invention

Embodiments of the invention relate to an interconnector for electrically connecting a plurality of solar cells and a solar cell module having the same.

2. Description of the Related Art

Recently, as existing energy sources such as petroleum and coal are expected to be depleted, interests in alternative energy sources for replacing the existing energy sources are increasing. Among the alternative energy sources, solar cells for generating electric energy from solar energy have been particularly spotlighted.

A solar cell generally includes a substrate and an emitter region, which are formed of semiconductors of different conductive types, for example, a p-type and an n-type, and electrodes respectively connected to the substrate and the emitter region. A p-n junction is formed at an interface between the substrate and the emitter region.

When light is incident on the solar cell having the above-described structure, electrons inside the semiconductors become free electrons (hereinafter referred to as ‘electrons’) by the photoelectric effect. Further, electrons and holes respectively move to the n-type semiconductor (for example, the emitter region) and the p-type semiconductor (for example, the substrate) based on the principle of the p-n junction. The electrons moving to the emitter region and the holes moving to the substrate are collected by the electrode connected to the emitter region and the electrode connected to the substrate, respectively.

Because the solar cell having the above-described configuration produces a very small amount of voltage and current, the plurality of solar cells are connected in series or parallel to one another so as to obtain a desired output. Thus, a moisture-proof solar cell module including the plurality of solar cells is manufactured in a panel form. An interconnector is used to electrically connect the solar cells of the solar cell module.

However, the size of a light receiving surface of each solar cell of the solar cell module is reduced because of the interconnector. More specifically, because the size of the light receiving surface of the solar cell is reduced by an area occupied by the interconnector, a photoelectric conversion efficiency of the solar cell module is reduced.

A solar cell module, in which solar cells are electrically connected to one another using an interconnector having an uneven surface, has been recently developed, so as to minimize such a problem. In the solar cell module, a portion (for example, light incident on the uneven surface of the interconnector) of light incident on a light receiving surface of each solar cell is reflected from the uneven surface of the interconnector and then is again incident on the light receiving surface of the solar cell due to a scattering effect of light.

The interconnector having the above-described configuration improves the photoelectric conversion efficiency of the solar cell module and thus increases an output of the solar cell module. However, in this instance, the uneven surface of the interconnector entirely occupies one surface of the interconnector. Therefore, when the adjacent solar cells are electrically connected using the interconnector having the uneven surface, an adhesion strength between the interconnector and a back surface of the substrate of the solar cell in a contact portion between an electrode part formed on the back surface of the substrate and the interconnector is reduced due to the uneven surface of the interconnector.

### SUMMARY OF THE INVENTION

Embodiments of the invention provide an interconnector with an improved adhesion strength with respect to an electrode part.

Embodiments of the invention also provide a solar cell module with an improved efficiency.

In one aspect, there is an interconnector including a conductive metal of a band shape including a first surface and a second surface opposite the first surface, and a solder coated on the first surface, wherein the first surface of the conductive metal includes an uneven surface, on which a plurality of convex portions each having a cross section of a pyramid shape are formed, and a flat surface which is substantially flat, wherein a shortest distance between a peak and a valley of the convex portion is greater than a shortest distance between the peak of the convex portion and the flat surface.

A height of the flat surface may be substantially equal to a height of the peak of the convex portion or may be greater than the height of the peak of the convex portion.

The uneven surface and the flat surface may be distinguished from each other in a width direction or a longitudinal direction of the interconnector.

When the uneven surface and the flat surface are distinguished from each other in the width direction of the interconnector, the flat surface may be formed in the middle of the first surface in the width direction of the interconnector, and the uneven surface may be formed on both sides of the flat surface in the width direction of the interconnector.

Alternatively, the uneven surface may be formed in the middle of the first surface in the width direction of the interconnector, and the flat surface may be formed on both sides of the uneven surface in the width direction of the interconnector.

In another aspect, there is a solar cell module including a plurality of solar cells, and an interconnector including a first area attached to a front electrode part of one solar cell of the plurality of solar cells, a second area attached to a back electrode part of other solar cell adjacent to the one solar cell, and a third area connecting the first area to the second area.

The interconnector includes a conductive metal of a band shape including a first surface and a second surface opposite the first surface, and a solder coated on the first surface. The second surface of the first area is attached to the front electrode part, and the first surface of the second area is attached to the back electrode part. The first surface of the conductive metal includes an uneven surface, on which a plurality of convex portions each having a cross section of a pyramid shape are formed, and a flat surface which is substantially flat. A shortest distance between the back electrode part and the flat surface is less than a shortest distance between the back electrode part and a valley of the convex portion.

The shortest distance between the back electrode part and the flat surface may be substantially equal to a shortest distance between the back electrode part and a peak of the convex portion.

Alternatively, the shortest distance between the back electrode part and the flat surface may be less than the shortest distance between the back electrode part and the peak of the convex portion.

The uneven surface and the flat surface may be distinguished from each other in a width direction or a longitudinal direction of the interconnector.

In this instance, the flat surface may be formed in the middle of the first surface in the width direction of the interconnector, and the uneven surface may be formed on both sides of the flat surface in the width direction of the interconnector.

Alternatively, the uneven surface may be formed in the middle of the first surface in the width direction of the interconnector, and the flat surface may be formed on both sides of the uneven surface in the width direction of the interconnector.

In another aspect, there is an interconnector including a conductive metal of a band shape including a first surface and a second surface opposite the first surface; and a solder coated on the first surface, wherein the first surface of the conductive metal includes at least a flattened peak extending in a length direction of the conductive metal, the flattened peak including an inclined portion and a flat portion extending in a width direction of the conductive metal, and wherein a length of the inclined portion is less than a length of the flat portion in the width direction of the conductive metal.

The conductive metal includes a plurality of sides in a cross section, including the flat portion, another flat portion that is parallel to the flat portion, the inclined portion connected to the flat portion, and at least one vertical portion connected to the another flat portion.

The inclined portion includes at least one inclined surface.

The inclined portion includes at least two inclined surfaces that form two sides that meet at a vertex.

A height of the flat portion is substantially equal to a height of the vertex.

A height of the flat portion is greater than a height of the vertex.

The vertex and the flat portion are distinguished from each other in the width direction of the conductive metal.

The flat portion is formed in a middle of the first surface in the width direction of the conductive metal, and the vertex is formed to at least one side of the flat portion in the width direction of the conductive metal.

The vertex is formed in a middle of the first surface in the width direction of the conductive metal, and the flat portion is formed to at least one side of the vertex in the width direction of the conductive metal.

The conductive metal includes at least one of a plurality of flat portions and a plurality of vertices.

At least one of the plurality of flat portion is formed in a middle of the first surface in the width direction of the conductive metal, and the plurality of vertices are formed to both sides of the at least one of the plurality of flat portions in the width direction of the conductive metal.

The plurality of vertices are formed in a middle of the first surface in the width direction of the conductive metal, and the plurality of flat portions are formed to both sides of the plurality of vertices in the width direction of the conductive metal.

In another aspect, there is a solar cell module including a plurality of solar cells; and an interconnector including a first area attached to a front electrode part of one solar cell of the plurality of solar cells, a second area attached to a back electrode part of other solar cell adjacent to the one solar cell, and a third area connecting the first area to the second area, wherein the interconnector includes a conductive metal of a band shape including a first surface and a second surface opposite the first surface, and a solder coated on the first surface, wherein the second surface of the first area is attached to the front electrode part, and the first surface of the second area is attached to the back electrode part, wherein the first surface of the conductive metal includes at least a flattened peak extending in a length direction of the conductive metal, the flattened peak including an inclined portion and a flat portion extending in a width direction of the conductive metal, and wherein a length of the inclined portion is less than a length of the flat portion in the width direction of the conductive metal.

According to the above-described characteristics of the embodiments of the invention, the first surface of the interconnector attached to the back electrode part of the solar cell includes the flat surface and the uneven surface, the solder is coated on the flat surface and the uneven surface, the shortest distance between the back electrode part and the flat surface is less than the shortest distance between the back electrode part and the valley of the convex portion.

Accordingly, an amount of the solder positioned between the back electrode part and the first surface having both the uneven surface and the flat surface is more than an amount of the solder positioned between the back electrode part and the first surface having only the uneven surface. Hence, an adhesion strength between the back electrode part and the interconnector may increase.

Further, because the second surface of the interconnector is attached to the front electrode part of the solar cell, light is scattered by the uneven surface of the first surface opposite the second surface. Hence, an amount of light incident on the solar cell may increase.

### BRIEF DESCRIPTION OF THE DRAWINGS

The accompanying drawings, which are included to provide a further understanding of the invention and are incorporated in and constitute a part of this specification, illustrate embodiments of the invention and together with the description serve to explain the principles of the invention. In the drawings:

FIG. 1 is an exploded perspective view of a solar cell module according to an example embodiment of the invention;

FIG. 2 is a partial perspective view of a solar cell shown in FIG. 1;

FIG. 3 is a side view showing an electrical connection structure of solar cells according to an example embodiment of the invention;

FIGS. 4A and 4B are a perspective view and a cross-sectional view in a width direction showing a portion of a second area of an interconnector according to a first embodiment of the invention, respectively;

FIG. 5 is a cross-sectional view showing an attachment state between the interconnector shown in FIGS. 4A and 4B and a solar cell;

FIGS. 6A and 6B are a perspective view and a cross-sectional view showing a portion of a second area of an interconnector according to a second embodiment of the invention, respectively;

FIG. 7 is a perspective view showing a portion of a second area of an interconnector according to a third embodiment of the invention; and

FIGS. 8A and 8B are a perspective view and a cross-sectional view showing a portion of a second area of an interconnector according to a fourth embodiment of the invention, respectively.

### DETAILED DESCRIPTION OF THE EMBODIMENTS

Reference will now be made in detail to embodiments of the invention examples of which are illustrated in the accompanying drawings. Since the invention may be modified in various ways and may have various forms, specific embodiments are illustrated in the drawings and are described in detail in this specification. However, it should be understood that the invention are not limited to specific disclosed embodiments, but include all modifications, equivalents and substitutes included within the spirit and technical scope of the invention.

The terms ‘first’, ‘second’, etc., may be used to describe various components, but the components are not limited by such terms. The terms are used only for the purpose of distinguishing one component from other components.

For example, a first component may be designated as a second component without departing from the scope of the embodiments of the invention. In the same manner, the second component may be designated as the first component.

The term “and/or” encompasses both combinations of the plurality of related items disclosed and any item from among the plurality of related items disclosed.

When an arbitrary component is described as “being connected to” or “being linked to” another component, this should be understood to mean that still another component(s) may exist between them, although the arbitrary component may be directly connected to, or linked to, the second component.

On the other hand, when an arbitrary component is described as “being directly connected to” or “being directly linked to” another component, this should be understood to mean that no component exists between them.

The terms used in this application are used to describe only specific embodiments or examples, and are not intended to limit the invention. A singular expression can include a plural expression as long as it does not have an apparently different meaning in context.

In this application, the terms “include” and “have” should be understood to be intended to designate that illustrated features, numbers, steps, operations, components, parts or combinations thereof exist and not to preclude the existence of one or more different features, numbers, steps, operations, components, parts or combinations thereof, or the possibility of the addition thereof.

In the drawings, the thickness of layers, films, panels, regions, etc., are exaggerated for clarity. It will be understood that when an element such as a layer, film, region, or substrate is referred to as being “on” another element, it can be directly on the other element or intervening elements may also be present. In contrast, when an element is referred to as being “directly on” another element, there are no intervening elements present.

Unless otherwise specified, all of the terms which are used herein, including the technical or scientific terms, have the same meanings as those that are generally understood by a person having ordinary knowledge in the art to which the embodiments of the invention.

The terms defined in a generally used dictionary must be understood to have meanings identical to those used in the context of a related art, and are not to be construed to have ideal or excessively formal meanings unless they are obviously specified in this application.

The following example embodiments of the invention are provided to those skilled in the art in order to describe the present invention more completely. Accordingly, shapes and sizes of elements shown in the drawings may be exaggerated for clarity.

Exemplary embodiments of the invention will be described with reference to FIGS. 1 to 8B.

FIG. 1 is an exploded perspective view of a solar cell module according to an example embodiment of the invention.

As shown in FIG. 1, a solar cell module 100 according to the embodiment of the invention includes a plurality of solar cells 10, interconnectors 20 for electrically connecting the solar cells 10 to one another, protective layers 30a and 30b for protecting the solar cells 10, a transparent member 40 positioned on the upper protective layer 30a which is positioned near to light receiving surfaces of the solar cells 10, a back sheet 50 underlying the lower protective layer 30b which is positioned near to surfaces of the solar cells 10 opposite the light receiving surfaces of the solar cells 10, a frame for receiving the components 10, 20, 30a, 30b, 40, and 50 which form an integral body through a lamination process, and a junction box for finally collecting a current and a voltage produced by the solar cells 10.

The back sheet 50 prevents moisture and oxygen from penetrating into a back surface of the solar cell module 100, thereby protecting the solar cells 10 from an external environment. The back sheet 150 may have a multi-layered structure including a moisture/oxygen penetrating prevention layer, a chemical corrosion prevention layer, an insulation layer, etc.

The lamination process is performed on the protective layers 30a and 30b in a state where the protective layers 30a and 30b are respectively positioned on and under the solar cells 10 to form an integral body of the protective layers 30a and 30b and the solar cells 10. Hence, the protective layers 30a and 30b prevent corrosion of the solar cells 10 resulting from the moisture penetration and protect the solar cells 10 from an impact. The protective layers 30a and 30b may be formed of ethylene vinyl acetate (EVA) or silicon resin. Other materials may be used.

The transparent member 40 on the upper protective layer 30a is formed of a tempered glass having a high transmittance and an excellent damage prevention function. The tempered glass may be a low iron tempered glass containing a small amount of iron. The transparent member 40 may have an embossed inner surface so as to increase a scattering effect of light.

A method of manufacturing the solar cell module 100 sequentially includes testing the solar cells 10, electrically connecting the tested solar cells 10 to one another using the interconnectors 20, sequentially disposing the back sheet 50, the lower protective layer 30b, the solar cells 10, the upper protective layer 30a, and the transparent member 40 on the bottom of the solar cell module 100 in the order named, performing the lamination process in a vacuum state to form an integral body of the components 10, 20, 30a, 30b, 40, and 50, performing an edge trimming process, testing the solar cell module 100, and the like.

FIG. 2 is a partial perspective view of the solar cell shown in FIG. 1. As shown in FIG. 2, each solar cell 10 includes a substrate 11, an emitter region 12 positioned at a first surface (for example, a front surface) of the substrate 11 on which light is incident, a plurality of first finger electrodes 13 positioned on the emitter region 12, at least one first bus bar electrode 14 which is positioned on the emitter region 12 in a direction crossing the first finger electrodes 13, a first dielectric layer 15 positioned on the emitter region 12 on which the first finger electrodes 13 and the at least one first bus bar electrode 14 are not positioned, and a second electrode 16 and a second bus bar electrode 17 which are positioned on a second surface (for example, a back surface) opposite the first surface of the substrate 11.

The solar cell 10 may further include a back surface field (BSF) region 18 between the second electrode 16 and the substrate 11. The back surface field region 18 is a region (for example, a p⁺-type region) which is more heavily doped than the substrate 11 with impurities of the same conductive type as the substrate 11.

The back surface field region 18 serves as a potential barrier of the substrate 11. Thus, because the back surface field region 18 prevents or reduces a recombination and/or a disappearance of electrons and holes at and around the back surface of the substrate 11, the efficiency of the solar cell 10 is improved.

The substrate 11 is a semiconductor substrate formed of first conductive type silicon, for example, p-type silicon, though not required. Silicon used in the substrate 11 may be single crystal silicon, polycrystalline silicon, or amorphous silicon. When the substrate 11 is of a p-type, the substrate 11 contains impurities of a group III element such as boron (B), gallium (Ga), and indium (In).

A texturing process may be performed on the surface of the substrate 11 to form the surface of the substrate 11 as a textured surface corresponding to an uneven surface or having uneven characteristics.

When the surface of the substrate 11 is the textured surface, a reflectance of light incident on a light receiving surface of the substrate 11 is reduced. Further, because both a light incident operation and a light reflection operation are performed on the textured surface of the substrate 11, light is confined in the solar cell 10. Hence, an absorption rate of light increases.

As a result, the efficiency of the solar cell 10 is improved. In addition, because a reflection loss of light incident on the substrate 11 decreases, an amount of light incident on the substrate 11 further increases.

The emitter region 12 is a region doped with impurities of a second conductive type (for example, an n-type) opposite the first conductive type of the substrate 11. The emitter region 12 forms a p-n junction along with the substrate 11.

When the emitter region 12 is of the n-type, the emitter region 12 may be formed by doping the substrate 11 with impurities of a group V element such as phosphorus (P), arsenic (As), and antimony (Sb).

When energy produced by light incident on the substrate 11 is applied to carriers inside the semiconductors, electrons move to the n-type semiconductor and holes move to the p-type semiconductor. Thus, when the substrate 11 is of the p-type and the emitter region 12 is of the n-type, the holes move to the substrate 11 and the electrons move to the emitter region 12.

Alternatively, the substrate 11 may be of an n-type and/or may be formed of a semiconductor material other than silicon. If the substrate 11 is of the n-type, the substrate 11 may contain impurities of a group V element such as phosphorus (P), arsenic (As), and antimony (Sb).

Because the emitter region 12 forms the p-n junction along with the substrate 11, the emitter region 12 may be of the p-type if the substrate 11 is of the n-type unlike the embodiment described above. In this instance, the electrons may move to the substrate 11, and the holes may move to the emitter region 12.

If the emitter region 12 is of the p-type, the emitter region 12 may be formed by doping the substrate 11 with impurities of a group III element such as boron (B), gallium (Ga), and indium (In).

The first dielectric layer 15 on the emitter region 12 may include at least one of a silicon nitride (SiNx) layer, a silicon dioxide (SiO₂) layer, and a titanium dioxide (TiO₂) layer.

The first dielectric layer 15 may serve as an anti-reflection layer, which reduces a reflectance of light incident on the solar cell 10 and increases selectivity of light of a predetermined wavelength band to thereby increase the efficiency of the solar cell 10.

Alternatively, the first dielectric layer 15 may serve as a passivation layer. Alternatively, the first dielectric layer 15 may simultaneously perform both an anti-reflection function and a passivation function, if necessary or desired.

The plurality of first finger electrodes 13 are formed on the emitter region 12 and are electrically and physically connected to the emitter region 12. The first finger electrodes 13 extend in a first direction X-X′ to be separated from one another. Each first finger electrode 13 collects carriers (for example, electrons) moving to the emitter region 12 and transfers the carriers to the first bus bar electrode 14.

The plurality of first finger electrodes 13 are formed of at least one conductive material. The conductive material may be at least one selected from the group consisting of nickel (Ni), copper (Cu), silver (Ag), aluminum (Al), tin (Sn), zinc (Zn), indium (In), titanium (Ti), gold (Au), and a combination thereof. Other conductive materials may be used for the first finger electrodes 13.

The plurality of first bus bar electrodes 14 are positioned on the emitter region 12. The first bus bar electrodes 14 extend in a second direction Y-Y′ crossing the first finger electrodes 13 and are electrically and physically connected to the emitter region 12 and the first finger electrodes 13.

Accordingly, the first finger electrodes 13 and the first bus bar electrodes 14 are positioned on the emitter region 12 in a crossing structure to configure front grid electrodes.

The first bus bar electrodes 14 are formed of at least one conductive material and are electrically connected to the emitter region 12 and the first finger electrodes 13. Thus, the first bus bar electrodes 14 output carriers (for example, electrons) transferred from the first finger electrodes 13 to an external device.

The conductive material forming the first bus bar electrodes 14 may be at least one selected from the group consisting of nickel (Ni), copper (Cu), silver (Ag), aluminum (Al), tin (Sn), zinc (Zn), indium (In), titanium (Ti), gold (Au), and a combination thereof. Other conductive materials may be used for the first bus bar electrodes 14.

In the embodiment disclosed herein, the first bus bar electrodes 14 may be formed of the same material as the first finger electrodes 13. For example, the first bus bar electrodes 14 may be formed of a conductive paste containing silver (Ag) or an alloy AgAl of silver (Ag) and aluminum (Al) as conductive particles.

The first finger electrodes 13 and the first bus bar electrodes 14 may be electrically connected to the emitter region 12 by applying the conductive paste including the conductive particles on the first dielectric layer 15, patterning the conductive paste in a grid pattern shown in FIG. 2, etching the first dielectric layer 15 using an etching component (for example, lead oxide (PbO)) contained in the conductive paste in a process for firing the patterned conductive paste.

The second electrode 16 on the back surface of the substrate 11 is formed as a sheet type conductive layer covering a remaining area excluding a formation portion of the second bus bar electrode 17 from the back surface of the substrate 11. The second electrode 16 collects carriers (for example, holes) moving to the substrate 11.

The sheet type second electrode 16 is formed of at least one conductive material. The conductive material may be at least one selected from the group consisting of nickel (Ni), copper (Cu), silver (Ag), aluminum (Al), tin (Sn), zinc (Zn), indium (In), titanium (Ti), gold (Au), and a combination thereof. Other conductive materials may be used for the second electrode 16.

For example, the second electrode 16 may be formed of aluminum (Al), so as to form the back surface field region at the back surface of the substrate 11.

When the back surface field region is positioned at the back surface of the substrate 11, the sheet type second electrode 16 may be electrically and physically connected to the back surface field region.

The plurality of second bus bar electrodes 17 on the back surface of the substrate 11 are positioned opposite the first bus bar electrodes 14 and extend in the second direction Y-Y′ to be separated from one another.

The second bus bar electrodes 17 are formed of at least one conductive material and are electrically connected to the sheet type second electrode 16. Thus, the second bus bar electrodes 17 output carriers (for example, holes) transferred from the second electrode 16 to the external device.

The conductive material forming the second bus bar electrodes 17 may be at least one selected from the group consisting of nickel (Ni), copper (Cu), silver (Ag), aluminum (Al), tin (Sn), zinc (Zn), indium (In), titanium (Ti), gold (Au), and a combination thereof. Other conductive materials may be used for the second bus bar electrodes 17.

In the embodiment disclosed herein, the second bus bar electrodes 17 may be formed of the same material as the first finger electrodes 13 and the first bus bar electrodes 14. For example, the second bus bar electrodes 17 may be formed of silver (Ag) or an alloy AgAl of silver (Ag) and aluminum (Al).

An operation of the solar cell 10 according to the embodiment of the invention having the above-described structure is described below.

When light irradiated onto the front surface of the solar cell 10 is incident on the substrate 11 through the first dielectric layer 15 and the emitter region 12, free electrons are generated by the photoelectric effect. Then, electrons move to the n-type emitter region 12 and holes move to the p-type substrate 11 based on a principle of the p-n junction.

The electrons moving to the n-type emitter region 12 are collected by the first finger electrodes 13 and then move to the first bus bar electrodes 14. The holes moving to the p-type substrate 11 are collected by the second electrode 16 and then move to the second bus bar electrodes 17.

The above-described solar cells 10 may be individually used. In addition, the plurality of solar cells 10 having the same structure may be electrically connected in series and/or in parallel to one another to form the solar cell module 100 for the efficient use of the solar cells 10.

An electrical connection structure of the solar cell module according to the embodiment of the invention is described below.

As shown in FIG. 1, the plurality of solar cells 10 are arranged in rows and columns to form a matrix structure. The number of solar cells 10 arranged on the row and/or the column of the matrix structure may be adjusted, if necessary or desired.

As shown in FIG. 3, the plurality of solar cells 10 are electrically connected to one another using the interconnectors 20. More specifically, the interconnector 20 electrically connects the first bus bar electrodes 14 of one solar cell 10 to the second bus bar electrodes 17 of other solar cell 10 adjacent to the one solar cell 10 in a state where the plurality of solar cells 10 are disposed to be adjacent to one another.

The interconnector 20 includes a first area A1 attached to the first bus bar electrodes 14 of one solar cell 10, a second area A2 attached to the second bus bar electrodes 17 of other solar cell 10 adjacent to the one solar cell 10, and a third area A3 connecting the first area A1 to the second area A2.

In the embodiment disclosed herein, a conductive adhesive film is used to attach the interconnector 20 to the bus bar electrodes 14 and 17.

More specifically, a plurality of conductive adhesive films 60 are positioned on the first bus bar electrodes 14 of the substrate 11 in the second direction Y-Y′.

FIG. 2 shows only one conductive adhesive film 60 as an example. However, the two or three conductive adhesive films 60 may be positioned on each of the first surface and the second surface of the substrate 11.

The conductive adhesive film 60 has a film shape in which a plurality of conductive particles are distributed in a resin.

A material of the resin is not particularly limited as long as it has the adhesion properties. It is preferable, but not required, that a thermosetting resin is used so as to increase the adhesion reliability.

The thermosetting resin may use at least one selected among epoxy resin, phenoxy resin, acryl resin, polyimide resin, and polycarbonate resin.

The resin may contain a predetermined material, for example, a known curing agent and a known curing accelerator, in addition to the thermosetting resin.

For example, the resin may contain a reforming material, such as a silane-based coupling agent, a titanate-based coupling agent, and an aluminate-based coupling agent, so as to improve an adhesion strength between the bus bar electrodes 14 and 17 and the interconnector 20. The resin may contain a dispersing agent, for example, calcium phosphate and calcium carbonate, so as to improve the dispersibility of the conductive particles. The resin may contain a rubber component, such as acrylic rubber, silicon rubber, and urethane rubber, so as to control the modulus of elasticity.

A material of the conductive particles is not particularly limited as long as it has the conductivity. The conductive particles may contain at least one metal selected among copper (Cu), silver (Ag), gold (Au), iron (Fe), nickel (Ni), lead (Pb), zinc (Zn), cobalt (Co), titanium (Ti), and magnesium (Mg) as the main component. The conductive particles may be formed of metal particles or metal-coated resin particles. The conductive adhesive film 60 having the above-described configuration may further include a peeling film.

It is preferable, but not required, that the conductive particles use the metal-coated resin particles, so as to mitigate a compressive stress of the conductive particles and improve the connection reliability of the conductive particles.

It is preferable, but not required, that the conductive particles each have a diameter of about 2 μm to 30 μm, so as to improve the dispersibility of the conductive particles.

It is preferable, but not required, that a composition amount of the conductive particles distributed in the resin is about 0.5% to 20% based on the total volume of the conductive adhesive film 60 in consideration of the connection reliability after the resin is cured.

When the composition amount of the conductive particles is less than about 0.5%, the current may not smoothly flow because of a reduction in a physical contact area between the bus bar electrodes 14 and 17 and the conductive particles. When the composition amount of the conductive particles is greater than about 20%, the adhesion strength between the bus bar electrodes 14 and 17 and the interconnector 20 may be reduced because a composition amount of the resin relatively decreases.

A heating temperature and an applied pressure are not particularly limited as long as the electrical connection and the adhesion maintenance are secured when a tabbing process is performed using the conductive adhesive film 60.

For example, the heating temperature may be set to a temperature range capable of curing the resin, for example, about 150° C. to 180° C. The applied pressure may be set to a pressure range capable of sufficiently attaching the bus bar electrodes 14 and 17, the conductive adhesive film 60, and the interconnector 20 to one another. Further, time required to heat and apply the pressure may be set to a range where the bus bar electrodes 14 and 17, the interconnector 20, etc., are not damaged or deformed by the heat.

So far, the embodiment of the invention described the typical solar cell, in which light is incident on one surface of the solar cell. However, the embodiment of the invention may be applied to a solar cell of a non-bus structure not including at least one of the first bus bar electrode 14 and the second bus bar electrode 17. Further, the embodiment of the invention may be applied to a bifacial solar cell.

It is possible to attach the interconnector 20 to the bus bar electrodes using a typical flux instead of the conductive adhesive film 60.

A structure of an interconnector according to a first embodiment of the invention is described below with reference to FIGS. 4A, 4B, and 5.

FIGS. 4A and 4B are a perspective view and a cross-sectional view in a width direction showing a portion of a second area of the interconnector according to the first embodiment of the invention, respectively. FIG. 5 is a cross-sectional view showing an attachment state between the interconnector shown in FIGS. 4A and 4B and a solar cell.

As shown in FIGS. 4A and 4B, an interconnector 20 according to the first embodiment of the invention includes a conductive metal 21 of a band shape. The conductive metal 21 is formed of a metal with the excellent conductivity, for example, Cu, A1, or Ag. The conductive metal 21 includes a first surface 21a and a second surface 21b opposite the first surface 21a.

As shown in FIG. 5, the interconnector 20 further includes a solder 23 coated on the first surface 21a and the second surface 21b of the conductive metal 21, so that the interconnector 20 is attached to the first bus bar electrode 14 and the second bus bar electrode 17.

The solder 23 coated on the surface of the conductive metal 21 is omitted in FIGS. 4A and 4B and is shown in FIG. 5. An adhesive material, for example, the conductive adhesive film 60 or the flux for attaching the interconnector 20 to the second bus bar electrode 17 is not shown for the simplicity of the drawing.

The second surface 21b of the first area A1 of the interconnector 20 is attached to the first bus bar electrode 14 of one solar cell, and the first surface 21a of the second area A2 of the interconnector 20 is attached to the second bus bar electrode 17 of other solar cell adjacent to the one solar cell.

The first surface 21a of the second area A2 has an uneven surface 21a-1 and a flat surface 21a-2.

As shown in FIGS. 4A and 4B, the uneven surface 21a-1 and the flat surface 21a-2 formed on the first surface 21a of the second area A2 may be distinguished from each other in a width direction X-X′ of the interconnector 20. For example, the flat surface 21a-2 may be formed in the middle of the first surface 21a in the width direction X-X′ of the interconnector 20, and the uneven surfaces 21a-1 may be formed on both sides of the flat surface 21a-2 in the width direction X-X′ of the interconnector 20, respectively.

On the contrary, the uneven surface 21a-1 and the flat surface 21a-2 formed on the first surface 21a of the second area A2 may be distinguished from each other in a longitudinal direction Y-Y′ of the interconnector 20.

A plurality of convex portions 21a′ each having a cross section of a pyramid shape are formed on the uneven surface 21a-1.

The flat surface 21a-2 is substantially flat unlike the uneven surface 21a-1. In the embodiment disclosed herein, “substantially flat” indicates that protrusions, such as the convex portions 21a′ formed on the uneven surface 21a-1, are not formed.

In the embodiment disclosed herein, because the first surface 21a of the second area A2 has the uneven surface 21a-1, an amount of light incident on the solar cell 10 may increase by reflecting light incident on the first surface 21a of the first area A1 of the interconnector 20.

Further, because the first surface 21a of the second area A2 has the flat surface 21a-2, the adhesion strength between the second bus bar electrode 17 and the interconnector 20 may increase by increasing an amount of the solder 23 formed between the second bus bar electrode 17 and the first surface 21a.

A shortest distance D1 between a peak and a valley of the convex portion 21a′ of the interconnector 20 is greater than a shortest distance D2 between the peak of the convex portion 21a′ and the flat surface 21a-2, so as to increase the adhesion strength between the second bus bar electrode 17 and the interconnector 20.

In this instance, a height H1 of the flat surface 21a-2 may be substantially equal to a height H2 of the peak of the convex portion 21a′ or may be greater than the height H2 of the peak of the convex portion 21a′.

On the other hand, as shown in FIG. 4B, the height H1 of the flat surface 21a-2 may be less than the height H2 of the peak of the convex portion 21a′. In this instance, it is preferable, but not required, that a difference (H2−H1) between the height H1 of the flat surface 21a-2 and the height H2 of the peak of the convex portion 21a′ is less than a thickness of the solder 23 in consideration of the thickness of the solder 23 coated on the surface of the conductive metal 21.

In an embodiment of the invention, the first surface 21a includes a flattened peak extending in a length direction of the conductive metal 21. The flattened peak includes an inclined portion and a flat portion extending in a width direction of the conductive metal 21. The inclined portion is one or more of the sides of the convex portion 21a′ and the flat portion is the flat surface 21a-2. The length of the inclined portion is less than a length of the flat portion in the width direction of the conductive metal 21. In embodiments of the invention, the conductive metal 21 includes a plurality of sides in a cross section, including the flat portion (the flat surface 21a-2), another flat portion (the second surface 21b) that is parallel to the flat portion, the inclined portion (one or more of the sides of the convex portion 21a′) connected to the flat portion, and at least one vertical portion connected to the another flat portion. In embodiments of the invention, the inclined portion includes at least one inclined surface. Additionally, in embodiments of the invention, the inclined portion includes at least two inclined surfaces that meet at a vertex.

Accordingly, as shown in FIG. 5, when the interconnector 20 having the above-described configuration is attached to the second bus bar electrode 17, a shortest distance D3 between the second bus bar electrode 17 and the flat surface 21a-2 is less than a shortest distance D4 between the second bus bar electrode 17 and the valley of the convex portion 21a′.

According to the above-described configuration of the interconnector 20, the second surface 21b is attached to the first bus bar electrode 14 in the first area A1 of the interconnector 20, and the first surface 21a is attached to the second bus bar electrode 17 in the second area A2 of the interconnector 20.

Accordingly, light incident on the first area A1 of the interconnector 20 is reflected from the convex portions 21a′ of the uneven surface 21a-1 of the first surface 21a and is again incident on the solar cell 10. Therefore, an amount of light incident on the solar cell 10 increases.

Further, the first surface 21a of the second area A2 has the flat surface 21a-2. Therefore, an amount of the solder 23 positioned between the second bus bar electrode 17 and the first surface 21a having the flat surface 21a-2 is more than an amount of the solder 23 positioned between the second bus bar electrode 17 and the first surface 21a not having the flat surface. Hence, the adhesion strength between the second bus bar electrode 17 and the interconnector 20 increases.

Hereinafter, a structure of an interconnector according to various embodiments of the invention is described with reference to the drawings. Structures and components identical or equivalent to those described above are designated with the same reference numerals, and a further description may be briefly made or may be entirely omitted.

FIGS. 6A and 6B are a perspective view and a cross-sectional view showing a portion of a second area of an interconnector according to a second embodiment of the invention, respectively. In an interconnector 20 according to the second embodiment of the invention, sizes of a plurality of convex portions 21a′ positioned on an uneven surface 21a-1 of a first surface 21a of a second area are non-uniform.

As shown in FIGS. 6A and 6B, the sizes of the plurality of convex portions 21a′ may gradually increase as they go to a flat surface 21a-2 of the first surface 21a. However, the embodiment of the invention is not limited thereto.

So far, the embodiments of the invention described that the convex portions 21a′ each have a linear prism shape extending along the second direction Y-Y′.

Alternatively, as shown in FIG. 7, the convex portions 21a′ may be formed to have a predetermined slope in an oblique direction of the first direction X-X′ and the second direction Y-Y′.

So far, the embodiments of the invention described the interconnector 20, which is configured such that the flat surface 21a-2 is formed in the middle of the interconnector 20 in a width direction of the interconnector 20, and the uneven surfaces 21a-1 are respectively formed on both sides of the flat surface 21a-2 in the width direction of the interconnector 20.

As shown in FIGS. 8A and 8B, the uneven surface 21a-1 may be formed in the middle of the interconnector 20 in the width direction X-X′ of the interconnector 20, and the flat surfaces 21a-2 may be respectively formed on both sides of the uneven surface 21a-1 in the width direction X-X′ of the interconnector 20.

Although embodiments have been described with reference to a number of illustrative embodiments thereof, it should be understood that numerous other modifications and embodiments can be devised by those skilled in the art that will fall within the scope of the principles of this disclosure. More particularly, various variations and modifications are possible in the component parts and/or arrangements of the subject combination arrangement within the scope of the disclosure, the drawings and the appended claims. In addition to variations and modifications in the component parts and/or arrangements, alternative uses will also be apparent to those skilled in the art.

What is claimed is:

1. An interconnector comprising:
a conductive metal of a band shape including a first surface and a second surface opposite the first surface; and
a solder coated on the first surface,
wherein the first surface of the conductive metal includes at least a flattened peak extending in a length direction of the conductive metal, the flattened peak including an inclined portion and a flat portion extending in a width direction of the conductive metal, and
wherein a length of the inclined portion is less than a length of the flat portion in the width direction of the conductive metal.

2. The interconnector of claim 1, wherein the conductive metal includes a plurality of sides in a cross section, including the flat portion, another flat portion that is parallel to the flat portion, the inclined portion connected to the flat portion, and at least one vertical portion connected to the another flat portion.

3. The interconnector of claim 1, wherein the inclined portion includes at least one inclined surface.

4. The interconnector of claim 3, wherein the inclined portion includes at least two inclined surfaces that meet at a vertex.

5. The interconnector of claim 4, wherein a height of the flat portion is substantially equal to a height of the vertex.

6. The interconnector of claim 4, wherein a height of the flat portion is greater than a height of the vertex.

7. The interconnector of claim 1, wherein the vertex and the flat portion are distinguished from each other in the width direction of the conductive metal.

8. The interconnector of claim 7, wherein the flat portion is formed in a middle of the first surface in the width direction of the conductive metal, and the vertex is formed to at least one side of the flat portion in the width direction of the conductive metal.

9. The interconnector of claim 7, wherein the vertex is formed in a middle of the first surface in the width direction of the conductive metal, and the flat portion is formed to at least one side of the vertex in the width direction of the conductive metal.

10. The interconnector of claim 4, wherein the conductive metal includes at least one of a plurality of flat portions and a plurality of vertices.

11. The interconnector of claim 10, wherein at least one of the plurality of flat portion is formed in a middle of the first surface in the width direction of the conductive metal, and the plurality of vertices are formed to both sides of the at least one of the plurality of flat portions in the width direction of the conductive metal.

12. The interconnector of claim 10, wherein the plurality of vertices are formed in a middle of the first surface in the width direction of the conductive metal, and the plurality of flat portions are formed to both sides of the plurality of vertices in the width direction of the conductive metal.

13. A solar cell module comprising:
a plurality of solar cells; and
an interconnector including a first area attached to a front electrode part of one solar cell of the plurality of solar cells, a second area attached to a back electrode part of other solar cell adjacent to the one solar cell, and a third area connecting the first area to the second area,
wherein the interconnector includes a conductive metal of a band shape including a first surface and a second surface opposite the first surface, and a solder coated on the first surface,
wherein the second surface of the first area is attached to the front electrode part, and the first surface of the second area is attached to the back electrode part,
wherein the first surface of the conductive metal includes at least a flattened peak extending in a length direction of the conductive metal, the flattened peak including an inclined portion and a flat portion extending in a width direction of the conductive metal, and
wherein a length of the inclined portion is less than a length of the flat portion in the width direction of the conductive metal.

14. The solar cell module of claim 13, wherein the conductive metal includes a plurality of sides in a cross section, including the flat portion, another flat portion that is parallel to the flat portion, the inclined portion connected to the flat portion, and at least one vertical portion connected to the another flat portion.

15. The solar cell module of claim 13, wherein the inclined portion includes at least one inclined surface.

16. The solar cell module of claim 15, wherein the inclined portion includes at least two inclined surfaces that meet at a vertex.

17. The solar cell module of claim 13, wherein a height of the flat portion is substantially equal to or greater than a height of the vertex.

18. The solar cell module of claim 16, wherein the conductive metal includes at least one of a plurality of flat portions and a plurality of vertices.

19. The solar cell module of claim 18, wherein at least one of the plurality of flat portion is formed in a middle of the first surface in the width direction of the conductive metal, and the plurality of vertices are formed to both sides of the at least one of the plurality of flat portions in the width direction of the conductive metal.

20. The solar cell module of claim 18, wherein the plurality of vertices are formed in a middle of the first surface in the width direction of the conductive metal, and the plurality of flat portions are formed to both sides of the plurality of vertices in the width direction of the conductive metal.
